(19) United States
(12) Patent Application Publication
(10) Pub. No.: US 2009/0087779 A1
(43) Pub. Date: Apr. 2, 2009

(54) PRINTING PLATE MATERIAL

(75) Inventor: Takahiro Mori, Tokyo (JP)

Correspondence Address: LUCAS & MERCANTI, LLP, 475 PARK AVENUE SOUTH, 15TH FLOOR, NEW YORK, NY, 10016, US

(73) Assignee: KONICA MINOLTA MEDICAL & GRAPHIC, INC., Tokyo (JP)

(21) Appl. No.: 12/297,584

(22) PCT Filed: Apr. 11, 2007
(86) PCT No.: PCT/JP2007/057957

§ 371 Date: Oct. 17, 2008

(30) Foreign Application Priority Data
Apr. 20, 2006 (JP) 2006116471

(51) Int. Cl. G03F 7/028; G03F 7/004; G03F 7/031

(52) U.S. Cl. 430/273.1; 430/286.1

(57) ABSTRACT

The invention provides a printing plate material having high sensitivity, excellent initial printability, excellent stability under room light, i.e., good workability or storage stability under room light, and reduced contamination of a printing press. The printing plate material comprises a support having a hydrophilic surface, and provided thereon, an on-press developable image formation layer (A) and an on-press developable overcoat layer (B) in that order, wherein the on-press developable image formation layer (A) contains (a1) through (a3) as shown below, and the on-press developable overcoat layer (B) contains (b) as shown below:

(a1) a radically polymerizable compound with an ethylenically unsaturated bond
(a2) a polymerization initiator capable of generating a radical on reaction with an infrared absorber
(a3) an infrared absorber
(b) water-insoluble particles formed of a composite of a water-insoluble compound (b1) having no ultraviolet absorbing capability and a compound (b2) having an ultraviolet absorbing capability.

### TECHNICAL FIELD

The present invention relates to a printing plate material, and particularly to a printing plate material capable of forming an image via a computer to plate (CTP) system.

### TECHNICAL BACKGROUND

A printing plate material for the CTP system, which is inexpensive, can be easily handled, and has a printing ability comparable with that of a PS plate, is required accompanied with the digitization of printing data. Recently, printing plate materials applied to various CTP systems (hereinafter referred to as CTP) recording with a violet (405 nm) to infrared laser have been proposed.

Of these CTP systems, there is a CTP system called a wet type CTP in which solubility of the image formation layer of a printing plate material is varied by imagewise exposure, followed by development with a liquid developer to form an image. However, this system has various problems, in that an exclusive alkali developer is required as in conventional PS plates, developability of developer used varies due to the developer conditions such as temperature or fatigue degree of the developer, image reproduction is not obtained, of handleability under room light is restricted.

On the other hand, a so-called processless CTP, which does not require special development (including on-press development), has been developed. The processless CTP has been noticed, since it can be applied to a printing press for a direct imaging (DI) system, in which an image is formed directly on a printing plate material mounted on the printing press to obtain a printing plate, and printing is carried out employing the printing plate.

As one example of the processless CTP, there is an ablation type CTP, for example, one which is disclosed in Japanese Patent O.P.I. Publication Nos. 8-507727, 6-186750, 6-199064, 7-314934, 10-58636 and 10-244773.

These references disclose that a hydrophilic layer or a lipophilic layer, either of which is a surface layer, is multilayered on a substrate. In the case of a lipophilic layer containing a light-to-heat conversion material formed below a hydrophilic layer as a surface layer, the hydrophilic layer is imagewise exposed to imagewise ablate and remove the hydrophilic layer via explosive heat generation of the hydrophilic layer, whereby the lipophilic layer is exposed to form image portions. However, since the ablated matter is scattered from a printing plate during exposure, an exposure device required to be equipped with a mechanism of removing the ablated matter via suction lacks versatility. There is also a problem such that sensitivity is generally low, since large energy is required for ablation, and use of the above-described exposure device results in lowering of productivity.

On the other hand, printing plate materials are also being developed which are capable of forming an image with no ablation, and do not require developing treatment with a specific developer or wiping treatment. For example, a processless CTP (hereinafter referred to as an on-press developable CTP) is disclosed which comprises an image formation layer containing thermoplastic particles and a water-soluble binder and is capable of developing with dampening water (see Patent Document 1).

Since an exposure device does not have to install a special mechanism for such an on-press developable CTP, the same exposure device as one for a wet type thermal CTP is usable. Further, it enables design for comparatively high sensitivity and makes it possible to obtain sufficient exposure productivity.

The common structure of the on-press development CTP is one in which an image formation layer capable of being subjected to on-press development is provided on a substrate having a hydrophilic surface. The image formation layer capable of being subjected to on-press development contains thermosensitive hydrophobic precursors such as thermoplastic hydrophobic resin particles or microcapsules encapsulating a hydrophobic compound and an on-press development accelerator such as a water soluble resin.

The above-described thermosensitive hydrophobic precursors are capable of being heat-fused or cross-linking the image formation layer itself due to heat generated via infrared laser exposure, whereby the image formation layer is fixed onto the hydrophilic surface of a substrate, exhibiting an effect of obtaining image intensity in which the layer is not removed even by a contact with a water roller and an ink roller in a printing press.

In recent years, an on-press developable CTP is proposed which comprises a light sensitive layer containing an infrared absorber, a radical polymerization initiator, a radically polymerizable compound and a polymeric binder, and is capable of forming an image by polymerization (see Patent Document 2).

A method employing polymerization (hereinafter referred to as a polymerization method) has possibility that provides high sensitivity and high printing durability as compared with a method producing heat fusion of the thermoplastic particles described above. The on-press developable CTP has possibility that it is subjected to various treatments under room light during a period from when it is imagewise exposed till when it is mounted on a press, and that the period is from several hours to several days. Since the polymerization initiator used in the polymerization method has sensitivity to light in the ultraviolet to visible light range, for example, so-called fogs occur and dot image density variation or background contamination is produced under white light, resulting in incapability of on-press development.

Attempt for overcoming such demerits of the polymerization type on-press developable CTP has been made. For example, a planographic printing plate material is disclosed which comprises an image recording layer capable of being removed by printing ink and/or dampening water and an overcoat layer in that order, wherein the image recording layer contains an infrared absorber, a polymerization initiator and a polymerizable compound, and the overcoat layer contains colorant (pigment) particles (Patent Document 3).

In this planographic printing plate material, it is disclosed that handleability under room light can be improved by employing colorant (pigment) particles having absorption maximum in the wavelength range of from 300 to 600 nm. However, the improvement of handleability under room light is not so sufficient, since the colorant (pigment) particles have a particle size of generally several hundreds nanometer and their light absorption is relatively weak.

The increase in the content of colorant (pigment) particles in the overcoat layer has problem that lowers oxygen shielding property of the overcoat layer, which results in lowering of sensitivity. Countermeasure, which increases the thickness of the overcoat layer without increasing the colorant (pigment) particle content in the overcoat layer and increases light absorption, has problem that lowers initial printability (lowers ink receptivity) and is likely to cause contamination of an ink roller or a dampening roller of a printing press due to residues remaining after peeling the overcoat layer. Further, countermeasure, which increases a coating amount of yellow-colored colorant (pigment) particles to enhance light absorption, has problem that results in marked contamination of dampening water or printing ink.

As is apparent from the above, techniques improving handleability under room light in the on-press developable CTP employing the polymerization method have not yet been found.

### Patent Document 1: Japanese Patent O.P.I. Publication No. 9-123387

### Patent Document 2: Japanese Patent O.P.I. Publication No. 2002-287334

### Patent Document 3: Japanese Patent O.P.I. Publication No. 2005-225107

### DISCLOSURE OF THE INVENTION

### Problems to be Solved by the Invention

An object of the invention is to provide a printing plate material having high sensitivity, excellent initial printability, excellent stability under room light, i.e., good workability or storage stability under room light, and reduced contamination of a printing press.

### Means for Solving the Problems

The above object of the present invention can be attained by the following constitutions.

1. A printing plate material, comprising a support having a hydrophilic surface, and provided thereon, an on-press developable image formation layer (A) and an on-press developable overcoat layer (B) in that order, wherein the on-press developable image formation layer (A) contains (a1) through (a3) as shown below, and the on-press developable overcoat layer (B) contains (b) as shown below.

(a1) A radically polymerizable compound with an ethylenically unsaturated bond
(a2) A polymerization initiator capable of generating a radical on reaction with an infrared absorber
(a3) An infrared absorber
(b) Water-insoluble particles formed of a composite of a water-insoluble compound (b1) having no ultraviolet absorbing capability and a compound (b2) having an ultraviolet absorbing capability.

2. The printing plate material of item 1, wherein the water-insoluble particles (b) are thermoplastic resin particles having an ultraviolet absorbing capability.

3. The printing plate material of item 1 or 2, wherein the compound (b2) having an ultraviolet absorbing capability has a benzotriazole partial structure or a benzophenone partial structure.

### EFFECTS OF THE INVENTION

The above constitution of the invention can provide a printing plate material having high sensitivity, excellent initial printability, excellent stability under room light, i.e., good workability or storage stability under room light, and reduced contamination of a printing press.

### PREFERRED EMBODIMENT FOR CARRYING OUT THE INVENTION

In the invention, a printing plate material is characterized in that it comprises a support having a hydrophilic surface, and provided thereon, an on-press developable image formation layer (A) and an on-press developable overcoat layer (B) in that order, wherein the on-press developable image formation layer (A) contains (a1) through (a3) as shown below, and the on-press developable overcoat layer (B) contains (b) as shown below.

(a1) A radically polymerizable compound with an ethylenically unsaturated bond
(a2) A polymerization initiator capable of generating a radical on reaction with an infrared absorber
(a3) An infrared absorber
(b) Water-insoluble particles formed of a composite of a water-insoluble compound (b1) having no ultraviolet absorbing capability and a compound (b2) having an ultraviolet absorbing capability

### (Overcoat Layer)

In the printing plate material of the invention, the on-press developable overcoat layer (B) contains (b) water-insoluble particles formed of a composite of a water-insoluble compound (b1) having no ultraviolet absorbing capability and a compound (b2) having an ultraviolet absorbing capability.

The on-press developable overcoat layer in the invention means a layer capable of being removed on a planographic printing press by dampening water and/or printing ink used during planographic printing.

Herein, the composite means that (b2) is enclosed in particulate (b1), (b2) is adhered onto the surface of particulate (b1), or (b) is particles formed of a mixture of (b1) and (b2).

The water-insoluble compound (b1) comprises a compound insolubilized in water by crosslinking or polymerization of a water-soluble compound. The water-insoluble compound means that a solubility of the compound in 100 g of 25° C. water is less than 0.1 g.

The water-insoluble particles (b) in the invention may be any particles as long as they are formed of the composite. The water-insoluble particles (b) are preferably thermoplastic resin particles having an ultraviolet absorbing capability, in which thermoplastic resin particles are used as (b1).

The overcoat layer is generally formed of a polymeric binder, which contains PVA (polyvinyl alcohol) mainly. The overcoat layer is formed on a light sensitive layer by coating on the light sensitive layer an aqueous coating solution in which PVA etc. are dissolved and drying. Therefore, the thermoplastic resin particles having an ultraviolet absorbing capability are preferably in the form of aqueous dispersion (hereinafter also referred to as latex).

Typical examples of the latex include an aqueous dispersion of acryl polymer, styrene-acryl polymer, acrylonitrile-acryl copolymer, vinyl acetate polymer; vinyl acetate-acryl copolymer, vinyl acetate-vinyl chloride copolymer, urethane polymer, silicone-acryl copolymer, acrylsilicone polymer, polyester, or epoxy polymer.

Usually, the latex can be obtained through emulsion polymerization. Surfactants and polymerization initiators used therein are those which are conventionally used. Synthesis methods of the latex are described in U.S. Pat. Nos. 2,852,368, 2,853,457, 3,411,911, 3,411,912 and 4,197,127; Belgian Patent Nos. 688,882, 691,360 and 712,823; Japanese Patent Publication No. 45-5331; and Japanese Patent O.P.I. Publication Nos. 60-18540, 51-130217, 58-137831 and 55-50240.

In the invention, the compound (b2) having an ultraviolet absorbing capability in the latex having an ultraviolet absorbing capability has preferably a benzotriazole partial structure or a benzophenone partial structure, and more preferably a benzotriazole partial structure.

In the invention, the benzotriazole partial structure is preferably represented by the following formula (1):

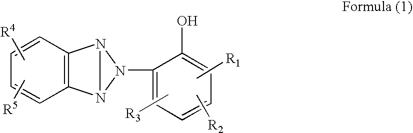

Next, a compound having the benzotriazole partial structure represented by formula (1) will be explained.

In formula (1), R₁, R₂, R₃, R₄ and R₅ may be the same or different, and independently represent a hydrogen atom, a halogen atom (chlorine, bromine, iodine, fluorine), a nitro group, a hydroxyl group, an alkyl group (for example, methyl, ethyl, n-propyl, isopropyl, aminopropyl, n-butyl, sec-butyl, tert-butyl, chlorobutyl, n-amyl, iso-amyl, hexyl, octyl, nonyl, stearylamidobutyl, decyl, dodecyl, pentadecyl, hexadecyl, cyclohexyl, benzyl, phenylethyl, phenylpropyl), an alkenyl group (for example, vinyl, allyl, methallyl, dodecenyl, tridecenyl, tetradecenyl, octadecenyl), an aryl group (for example, phenyl, 4-methylphenyl, 4-ethoxylphenyl, 2-hexoxylphenyl, 3-hexoxylphenyl), an alkoxy group (for example, methoxy, ethoxy, propoxy, butoxy, chlorobutoxy, decoxy, pentadecoxy, octadecoxy), an acyloxy group (for example, carbomethoxy, carbobutoxy, carbohexoxy, carbopentadecoxy), an aryloxy group (for example, phenoxy, 4-methylphenoxy, 2-propylphenoxy, 3-amylphenoxy), an alkylthio group (for example, methylthio, ethylthio, n-propyl, tert-butylthio, octylthio, benzylthio), an arylthio group (for example, phenylthio, methylphenylthio, ethylphenylthio, methoxylphenylthio, ethoxylphenylthio, naphthylthio), a mono- or di-alkylamino group (for example, N-ethylamino, N-t-octylamino, N,N-diethylamino, N,N-di-t-butylamino), an acylamino group (for example, acetylamino, benzoylamino, methanesulfonylamino), or a 5- or 6-membered heterocyclic ring containing an oxygen or nitrogen atom (for example, piperidino, morpholino, pyrrolidino, piperazino), provided that R₄ and R₅ may combine with each other to form a hydrocarbon ring.

In formula (1), the substituent represented by R₁ through R₅ preferably has 5-36 carbon atoms, and the alkyl group has 1 to 18 carbon atoms.

Examples of a compound represented by formula (1) will be listed below, but are not limited thereto

Ultraviolet-1-1: 2-(2′-Hydroxy-5′-t-butylphenyl)-benzotriazole
Ultraviolet-1-2: 2-(2′-Hydroxy-3,5′-di-t-butylphenyl)benzotriazole
Ultraviolet-1-3: 2-(2′-Hydroxy-3′-t-butyl-5′-methylphenyl)-5-chlorobenzo-triazole
Ultraviolet-1-4: 2-(2′-Hydroxy-3′,5′-di-t-butylphenyl)-5-chlorobenzotriazole
Ultraviolet-1-5: 2-(2′-Hydroxy-5′-isooctylphenyl)-benzotriazole
Ultraviolet-1-6: 2-(2′-Hydroxy-5′-n-octylphenyl)-benzotriazole
Ultraviolet-1-7: 2-(2′-Hydroxy-3′,5′-di-t-amylphenyl)-benzotriazole
Ultraviolet-1-8: 2-(2′-Hydroxy-5′-dodecylphenyl)-benzotriazole
Ultraviolet-1-9: 2-(2′-Hydroxy-5′-hexadecylphenyl)-benzotriazole
Ultraviolet-1-10: 2-(2′-Hydroxy-3′-t-amyl-5′-benzophenyl)-benzotriazole

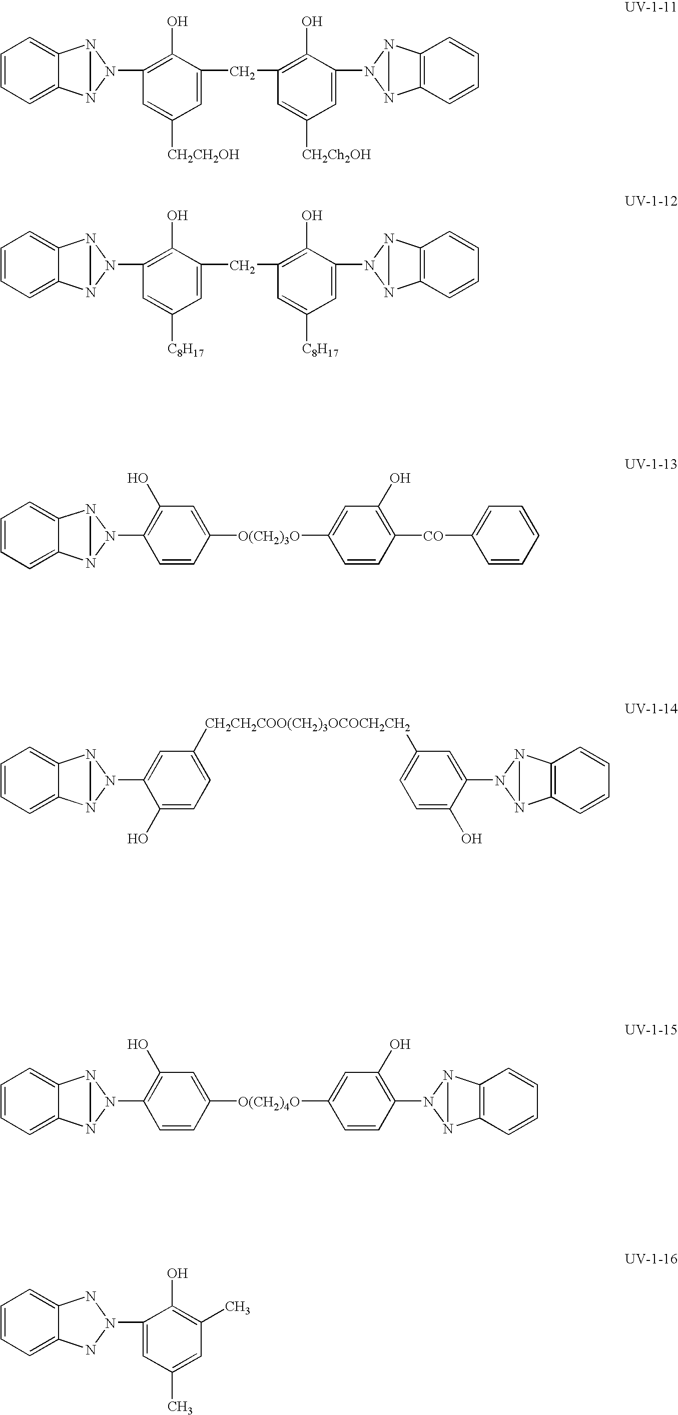

The benzophenone partial structure is preferably represented by the following formula (2):

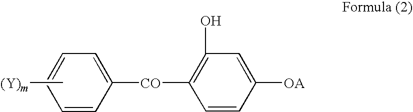

In formula (2), Y represents a hydrogen atom or a halogen atom, or an alkyl group, an alkenyl group or a phenyl group, provided that the alkyl group, the alkenyl group or the phenyl group may have a substituent; A represents a hydrogen atom, an alkyl group, an alkenyl group, a phenyl group, a cycloalkyl group, an alkylcarbonyl group, an alkylsulfonyl group or —CO(NH)ₙ₋₁-D in which D represents an alkyl group or an alkenyl group or a substituted or unsubstituted phenyl group 2; and m and n represent 1 or 2.

In the above, the alkyl group includes a straight-chained or branched aliphatic group having 1 to 24 carbon atoms, the alkoxy group includes an alkoxy group having 1 to 18 carbon atoms, the alkenyl group includes an alkenyl group having 2 to 16 carbon atoms, for example, an allyl group or a 2-butenyl group. The substituent of the alkyl, alkenyl or phenyl group includes a halogen atom, for example, a chlorine, bromine or fluorine atom, a hydroxy group or a phenyl group which may further have an alkyl group or a halogen atom as a substituent.

Examples of a compound represented by formula (2) will be listed below, but are not limited thereto.

### Ultraviolet-2-1: 2,4-Dihydroxybenzophenone

Ultraviolet-2-2: 2,2′-Dihydroxy-4-methoxybenzophenone
Ultraviolet-2-3: 2-hydroxy-4-methoxy-5-sulfobenzophenone
Ultraviolet-2-4: Bis(2-Methoxy-4-hydroxy-5-benzoylphenylmethane)

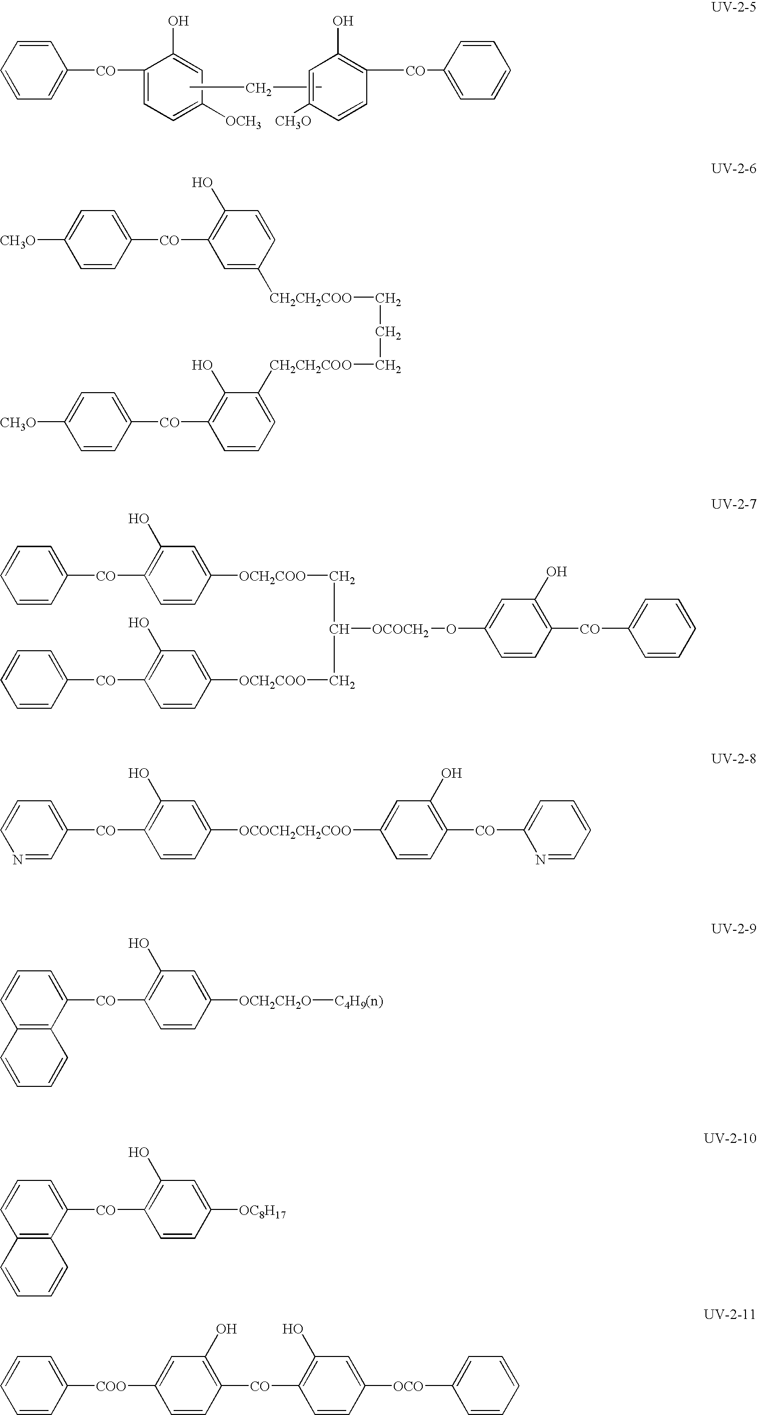

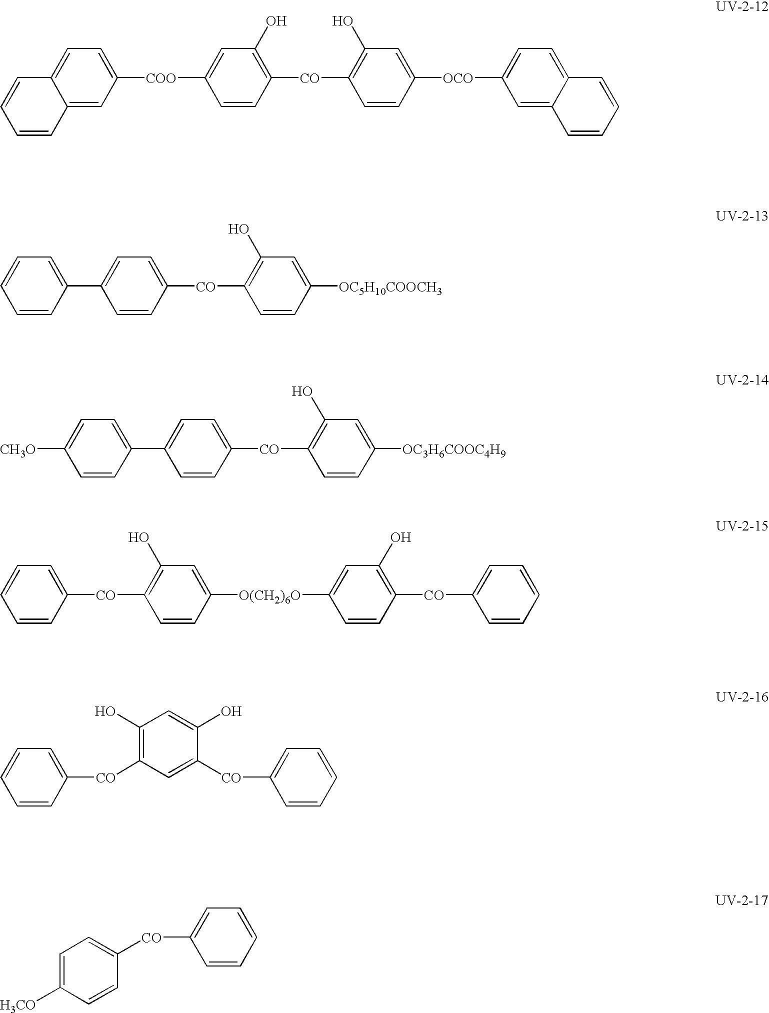

As a method for adding a compound having an ultraviolet absorbing capability in the latex, there is a method in which a compound having an ultraviolet absorbing capability is dissolved in an organic solvent such as alcohol, methylene chloride or dioxolane, added to latex during preparation of latex, and is incorporated into the latex particles; a method in which a compound having an ultraviolet absorbing capability is added to latex during preparation of latex, and incorporated in the side chain of latex structure; and a method in which a polymerizable monomer having, as a part of the chemical structure, a structure represented by formula (1) or (2) in the invention is copolymerized with another monomer, whereby a compound having an ultraviolet absorbing capability is introduced in the latex.

The adding amount of the compound having an ultraviolet absorbing capability is generally from 10 to 100% by weight, and preferably from 30 to 70% by weight, based on the latex, although it is different depending on kinds or ultraviolet absorbing capability of the compound.

In the invention, the minimum film forming temperature (MFT) of the latex having an ultraviolet absorbing capability is preferably from 0 to 100° C. In the invention, a film forming aid may be added to control the minimum film forming temperature of the latex. Such a film forming aid is called a plasticizer, and is an organic compound (usually an organic solvent), which lowers the minimum film forming temperature of the polymer latex. Such an organic compound is described, for example, in S. Muroi, “Gousei Latex no Kagaku (Chemistry of Synthesized Latex)”, published by Koubunshi Kankoukai (1970).

The average particle size of the water-insoluble particles (b) is preferably not more than 150 nm, more preferably from 10 to 150 nm, and still more preferably from 10 to 100 nm.

The content of the water-insoluble particles (b) in the invention of the overcoat layer is preferably from 1 to 80% by weight, and more preferably from 15 to 60% by weight.

The average particle size of the latex can be easily measured by a particle size measuring apparatus available on the market utilizing a light scattering method or a laser Doppler method, for example, Zetasizer 1000 (Malvern Co. Ltd.).

It is preferred that the overcoat layer in the invention contains a polymeric binder in order to carry the components described above.

As the polymeric binder, polyvinyl alcohol or polyvinyl pyrrolidone is preferably used in view of prevention of oxygen transmission or adhesion of the overcoat layer to the image formation layer.

Besides the above two polymers, a water soluble polymer such as polysaccharide, polyethylene glycol, gelatin, glue, casein, hydroxyethyl cellulose, carboxymethyl cellulose, methyl cellulose, hydroxyethyl starch, gum arabic, sucrose octaacetate, ammonium alginate, sodium alginate, polyvinyl amine, polyethylene oxide, polystyrene sulfonic acid, polyacrylic acid or a water soluble polyamide is used in combination.

The overcoat layer is provided so that adhesive strength between the protective layer and the light sensitive layer is preferably not less than 35 mN/mm, more preferably not less than 50 mN/mm, and still more preferably not less than 75 mN/mm.

The overcoat layer may further contain a surfactant or a matting agent as necessary. The overcoat layer is formed, coating on the image formation layer a coating solution in which the components described above in the overcoat layer are dissolved in an appropriate coating solvent, and drying.

The main solvent of the coating solution is preferably water or an alcohol solvent such as methanol, ethanol or isopropanol.

The thickness of the overcoat layer in the invention is preferably from 0.1 to 5.0 μm, and more preferably from 0.5 to 3.0 μm.

### (Image Formation Layer)

The image formation layer in the invention is an on-press developable layer and contains (a1) a radically polymerizable compound with an ethylenically unsaturated bond, (a2) a polymerization initiator capable of generating a radical on reaction with an infrared absorber, and (a3) an infrared absorber.

Herein, the on-press developable image formation layer means a layer such that after the printing plate material is imagewise exposed and mounted on a planographic printing press, the non-image portions of the image formation layer are capable of being removed with dampening water or both dampening water and printing ink used during planographic printing.

(a1) Radically Polymerizable Compound with Ethylenically Unsaturated Bond

The radically polymerizable compound with an ethylenically unsaturated bond is a compound having in the molecule a polymerizable unsaturated group. Examples thereof include conventional radically polymerizable monomers, and polyfunctional monomers and polyfunctional oligomers each having plural ethylenically unsaturated.

These monomers or oligomers are not specifically limited, but preferred examples thereof include a monofunctional acrylate such as 2-ethylhexyl acrylate, 2-hydroxypropyl acrylate, glycerol acrylate, tetrahydrofurfuryl acrylate, phenoxyethyl acrylate, nonylphenoxyethyl acrylate, tetrahydrofurfuryloxyethyl acrylate, tetrahydrofurfuryloxy-hexyl acrylate, acrylate of a 1,3-dioxanealcohol ε-caprolactone adduct or 1,3-dioxolanyl acrylate; a methacrylate, itaconate, crotonate or maleate alternative of the above acrylate; a bifunctional acrylate such as ethyleneglycol diacrylate, triethyleneglycol diacrylate, pentaerythritol diacrylate, hydroquinone diacrylate, resorcin diacrylate, hexanediol diacrylate, neopentyl glycol diacrylate, tripropylene glycol diacrylate, hydroxypivalic acid neopentyl glycol diacrylate, neopentyl glycol adipate diacrylate, diacrylate of hydroxypivalic acid neopentyl glycol-ε-caprolactone adduct, 2-(2-hydroxy-1,1-dimethylethyl)-5-hydroxymethyl-5-ethyl-1,3-dioxane diacrylate, tricyclodecanedimethylol acrylate, tricyclodecanedimethylol acrylate-ε-caprolactone adduct or 1,6-hexanediol diglycidylether diacrylate; a dimethacrylate, diitaconate, dicrotonate or dimaleate alternative of the above diacrylate; a polyfunctional acrylate such as trimethylolpropane triacrylate, ditrimethylolpropane tetraacrylate, trimethylolethane triacrylate, pentaerythritol triacrylate, pentaerythritol tetraacrylate, dipentaerythritol tetraacrylate, dipentaerythritol pentaacrylate, dipentaerythritol hexacrylate, dipentaerythritol hexacrylate-ε-caprolactone adduct, pyrrogallol triacrylate, propionic acid dipentaerythritol triacrylate, propionic acid dipentaerythritol tetraacrylate, or hydroxypivalylaldehyde modified dimethylolpropane triacrylate; and a methacrylate, itaconate, crotonate or maleate alternative of the above polyfunctional acrylate.

A prepolymer can be used as described above, and the prepolymer can be used singly, or in combination with the above described monomers and/or oligomers.

Examples of the prepolymer include polyester (meth)acrylate obtained by incorporating (meth)acrylic acid in a polyester of a polybasic acid such as adipic acid, trimellitic acid, maleic acid, phthalic acid, terephthalic acid, hymic acid, malonic acid, succinic acid, glutaric acid, itaconic acid, pyromellitic acid, fumalic acid, pimelic acid, sebatic acid, dodecanic acid or tetrahydrophthalic acid with a polyol such as ethylene glycol, ethylene glycol, diethylene glycol, propylene oxide, 1,4-butane diol, triethylene glycol, tetraethylene glycol, polyethylene glycol, grycerin, trimethylol propane, pentaerythritol, sorbitol, 1,6-hexanediol or 1,2,6-hexanetriol; an epoxyacrylate such as bisphenol A.epichlorhydrin.(meth)acrylic acid or phenol novolak.epichlorhydrin.(meth)acrylic acid obtained by incorporating (meth)acrylic acid in an epoxy resin; an urethaneacrylate such as ethylene glycol.adipic acid.tolylenediisocyanate.2-hydroxyethylacrylate, polyethylene glycol.tolylenediisocyanate.2-hydroxyethylacrylate, hydroxyethylphthalyl methacrylate.xylenediisocyanate, 1,2-polybutadieneglycol.tolylenediisocyanate.2-hydroxyethylacrylate or trimethylolpropane.propylene glycol.tolylenediisocyanate.2-hydroxyethylacrylate, obtained by incorporating (meth)acrylic acid in an urethane resin; a silicone acrylate such as polysiloxane acrylate, or polysiloxane.diisocyanate.2-hydroxyethylacrylate; an alkyd modified acrylate obtained by incorporating a methacroyl group in an oil modified alkyd resin; and a spiran resin acrylate.

The image formation layer can contain a monomer such as a phosphazene monomer, triethylene glycol, an EO modified isocyanuric acid diacrylate, an EO modified isocyanuric acid triacrylate, dimethyloltricyclodecane diacrylate, trimethylolpropane acrylate benzoate, an alkylene glycol acrylate, or a urethane modified acrylate, or an addition polymerizable oligomer or prepolymer having a structural unit derived from the above monomer.

Besides the above compounds, compounds disclosed in Japanese Patent O.P.I. Publication Nos. 58-212994, 61-6649, 62-46688, 62-48589, 62-173295, 62-187092, 63-67189, and 1-244891, compounds described on pages 286 to 294 of “11290 Chemical Compounds” edited by Kagakukogyo Nipposha, and compounds described on pages 11 to 65 of “UV•EB Koka Handbook (Materials)” edited by Kobunshi Kankokai can be suitably used. Of these compounds, compounds having two or more acryl or methacryl groups in the molecule are preferable, and those having a molecular weight of not more than 10,000, and preferably not more than 5,000 are more preferable.

An addition-polymerizable ethylenically double bond-containing monomer having a tertiary amino group in the molecule can be used preferably. The monomer is not specifically limited to the chemical structure, but is preferably a hydroxyl group-containing tertiary amine modified with glycidyl methacrylate, methacrylic acid chloride or acrylic acid chloride. Typically, a polymerizable compound is preferably used which is disclosed in Japanese Patent O.P.I. Publication Nos. 1-165613 and 1-203413.

In the invention, a reaction product of a polyhydric alcohol having a tertiary amino group in the molecule, a diisocyanate and a compound having in the molecule a hydroxyl group and an addition polymerizable ethylenically double bond is preferably used. A compound having a tertiary amino group and an amide bond in the molecule is especially preferred.

Examples of the polyhydric alcohol having a tertiary amino group in the molecule include triethanolamine, N-methyldiethanolamine, N-ethyldiethanolamine, N-n-butyldiethanolamine, N-tert-butyldiethanolamine, N,N-dihydroxyethyl)aniline, N,N,N′,N′-tetra-2-hydroxypropylethylenediamine, p-tolyldiethanolamine, N,N,N′, N′-tetra-2-hydroxyethylethylenediamine, N,N-bis(2-hydroxypropyl)aniline, allyldiethanolamine, 3-dimethylamino-1,2-propane diol, 3-diethylamino-1,2-propane diol, N,N-di(n-propylamino)-2,3-propane diol, N,N-di(iso-propylamino)-2,3-propane diol, and 3-(N-methyl-N-benzylamino)-1,2-propane diol, but the invention is not specifically limited thereto.

Examples of the diisocyanate include butane-1,4-diisocyanate, hexane-1,6-diisocyanate, 2-methylpentane-1,5-diisocyanate, octane-1,8-diisocyanate, 1,3-diisocyanatomethylcyclohexanone, 2,2,4-trimethylhexane-1,6-diisocyanate, isophorone diisocyanate, 1,2-phenylene diisocyanate, 1,3-phenylene diisocyanate, 1,4-phenylene diisocyanate, tolylene-2,4-diisocyanate, tolylene-2,5-diisocyanate, tolylene-2,6-diisocyanate, 1,3-di(isocyanatomethyl)benzene, and 1,3-bis(1-isocyanato-1-methylethyl)benzene, but the invention is not specifically limited thereto.

Examples of the compound having a hydroxyl group and an addition polymerizable ethylenically double bond in the molecule is not specifically limited, but 2-hydroxyethyl methacrylate, 2-hydroxyethyl acrylate, 4-hydroxybutyl acrylate, 2-hydroxypropylene-1,3-dimethacrylate, and 2-hydroxypropylene-1-methacrylate-3-acrylate are preferred.

The reaction product can be synthesized according to the same method as a conventional method in which a urethaneacrylate compound is ordinarily synthesized employing a diol, a diisocyanate and an acrylate having a hydroxyl group.

Examples of the reaction product of a polyhydric alcohol having a tertiary amino group in the molecule, a diisocyanate and a compound having in the molecule a hydroxyl group and an addition polymerizable ethylenically double bond will be listed below.

M-1: A reaction product of triethanolamine (1 mole), hexane-1,6-diisocyanate (3 moles), and 2-hydroxyethyl methacrylate (3 moles)
M-2: A reaction product of triethanolamine (1 mole), isophorone diisocyanate (3 moles), and 2-hydroxyethyl methacrylate (3 moles)
M-3: A reaction product of N-n-butyldiethanolamine (1 mole), 1,3-bis(1-isocyanato-1-methylethyl)benzene (2 moles), and 2-hydroxypropylene-1-methacrylate-3-acrylate (2 moles)
M-4: A reaction product of N-n-butyldiethanolamine (1 mole), 1,3-di(isocyanatomethyl)benzene (2 moles), and 2-hydroxypropylene-1-methacrylate-3-acrylate (2 moles)
M-5: A reaction product of N-methydiethanolamine (1 mole), tolylene-2,4-diisocyanate (2 moles), and 2-hydroxypropylene-1,3-dimethacrylate (2 moles)
M-6: A reaction product of triethanolamine (1 mole), 1,3-bis(1-isocyanato-1-methylethyl)benzene (3 moles), and 2-hydroxyethyl methacrylate (3 moles)
M-7: A reaction product of ethylenediamine tetraethanol (1 mole), 1,3-bis(1-isocyanato-1-methylethyl)benzene (4 moles), and 2-hydroxyethyl methacrylate (4 moles)

In addition to the above, acrylates or methacrylates disclosed in Japanese Patent O.P.I. Publication Nos. 1-105238 and 2-127404 can be used.

The content of the radically polymerizable compound with an ethylenically unsaturated bond in the image formation layer is preferably from 5 to 80% by weight, and more preferably from 15 to 60% by weight.

(a2) Polymerization Initiator

The polymerization initiator in the invention is one capable of generating an acid on reaction with an infrared absorber. As the polymerization initiator capable of generating an acid on reaction with an infrared absorber, a compound known as an acid generating agent can be suitably used.

As the acid generating agent, there are various conventional compounds and mixtures.

There are, for example, a salt of diazonium, phosphonium, sulfonium or iodonium ion with BF₄⁻, PF₆⁻, SbF₆⁻ SiF₆²⁻ or ClO₄⁻, an organic halogen compound, o-quinonediazide sulfonylchloride and a mixture of an organic metal and an organic halogen compound.

Preferred examples of the polymerization initiator suitably used in the invention will be explained below.

Firstly, a salt of an aromatic onium compound such as diazonium, ammonium, iodonium, sulfonium or phosphonium with B(C₆F₅)₄⁻, PF₆⁻, AsF₆⁻, SbF₆⁻ or CF₃SO₃⁻ can be cited. Examples thereof will be listed below.

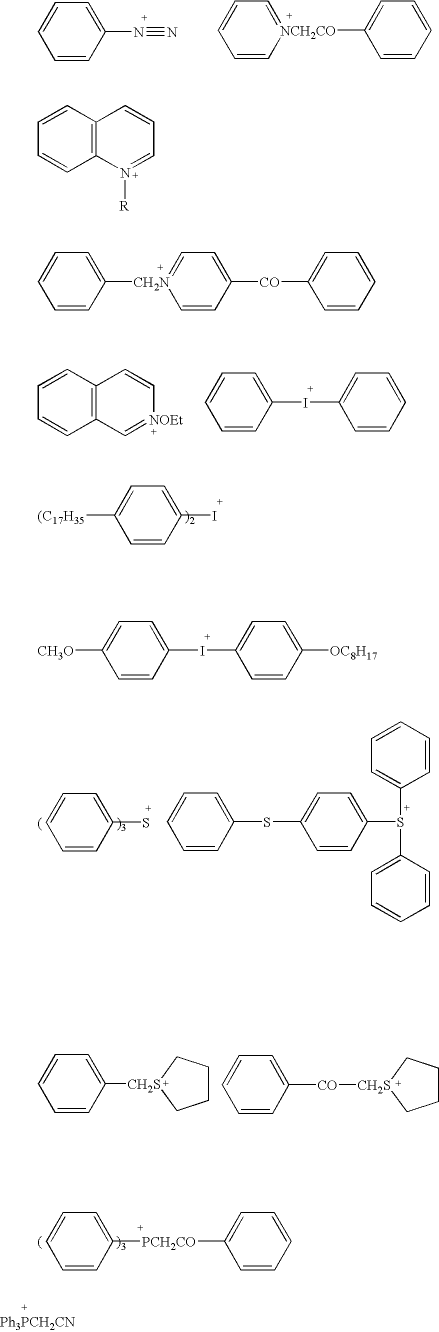

Secondly, a sulfonated compound generating sulfonic acid salt can be cited. Typical examples thereof will be listed below.

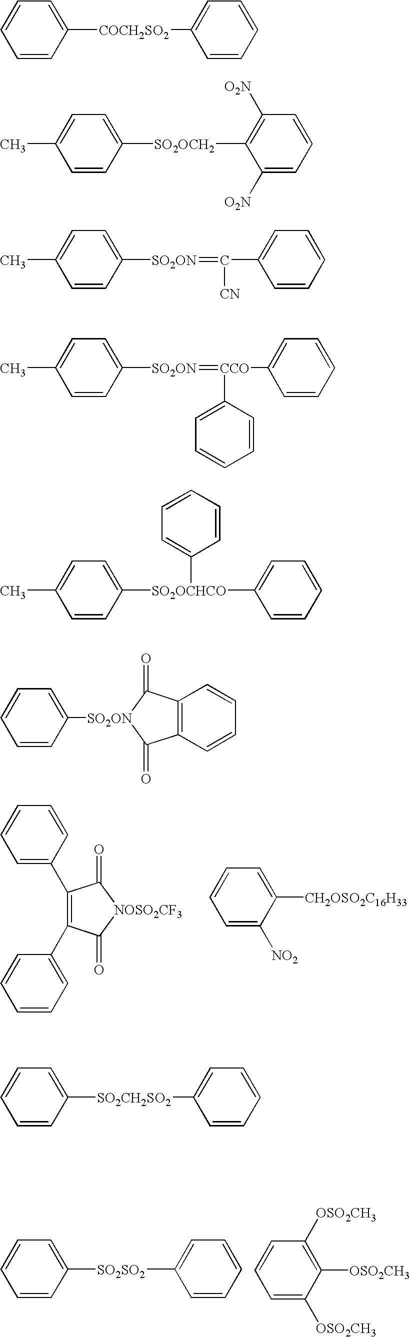

Thirdly, a polyhalogen compound can be cited. The polyhalogen compound herein referred to is a compound having a trihalomethyl group, a dihalomethyl group or a dihalomethylene group. In the invention, an oxadiazole compound having in the molecule the group described above as the substituent or a polyhalogen compound represented by the following formula (1) is preferably used. A polyhalogen compound represented by the following formula (2) is more preferably used.

R¹—CY₂—(C═O)—R² Formula (1)

wherein R¹ represents a hydrogen atom, a halogen atom, an alkyl group, an aryl group, an acyl group, an alkylsulfonyl group, an arylsulfonyl group, an iminosulfo group or a cyano group; R² represents a monovalent substituent, provided that R¹ and R² may combine with each other to form a ring; and Y represents a halogen atom.

CY₃—(C═O)—X—R³ Formula (2)

wherein R³ represents a monovalent substituent; X represents —O— or —NR⁴— in which R⁴ represents a hydrogen atom or an alkyl group, provided that R³ and R⁴ may combine with each other to form a ring; and Y represents a halogen atom.

Among these, a polyhalogen compound having a polyhaloacetylamido group is preferably used.

The polymerization initiator in the invention (a2) may be used singly or as an admixture of two or more kinds thereof.

The content of the polymerization initiator in the invention is preferably from about 0.1 to about 20% by weight, and more preferably from 0.2 to 10% by weight, based on the total solid weight of image formation layer.

(a3) Infrared Absorber

The infrared absorber in the invention is a compound having light absorption in the wavelength range of from 700 to 1200 nm. The infrared absorber having light absorption in the wavelength range of from 700 to 1200 nm is not specifically limited. Examples thereof include infrared absorbers, light-to-heat conversion materials, near-infrared dyes or pigments disclosed in U.S. Pat. No. 5,340,699, and Japanese Patent O.P.I. Publication Nos. 2001-175006, 2002-537419, 2002-341519, 2003-76010, 2002-278057, 2003-5363, 2001-125260, 2002-23360, 2002-40638, 2002-62642, and 2002-2787057.

Cyanine dyes, squarylium dyes, oxonol dyes, pyrylium dyes, thiopyrylium dyes, polymethine dyes, oil-soluble phthalocyanine dyes, triarylamine dyes, thiazolium dyes, oxazolium dyes, polyaniline dyes, polypyrrole dyes and polythiophene dyes, can be preferably employed.

Besides the above, pigments such as carbon black, titanium black, iron oxide powder and colloidal silver can be preferably used. Cyanine dyes are preferred of the dyes and carbon black is preferred of the pigments, in view of extinction coefficient, light to heat conversion efficiency or price.

Preferred examples of the cyanine dyes will be listed below.

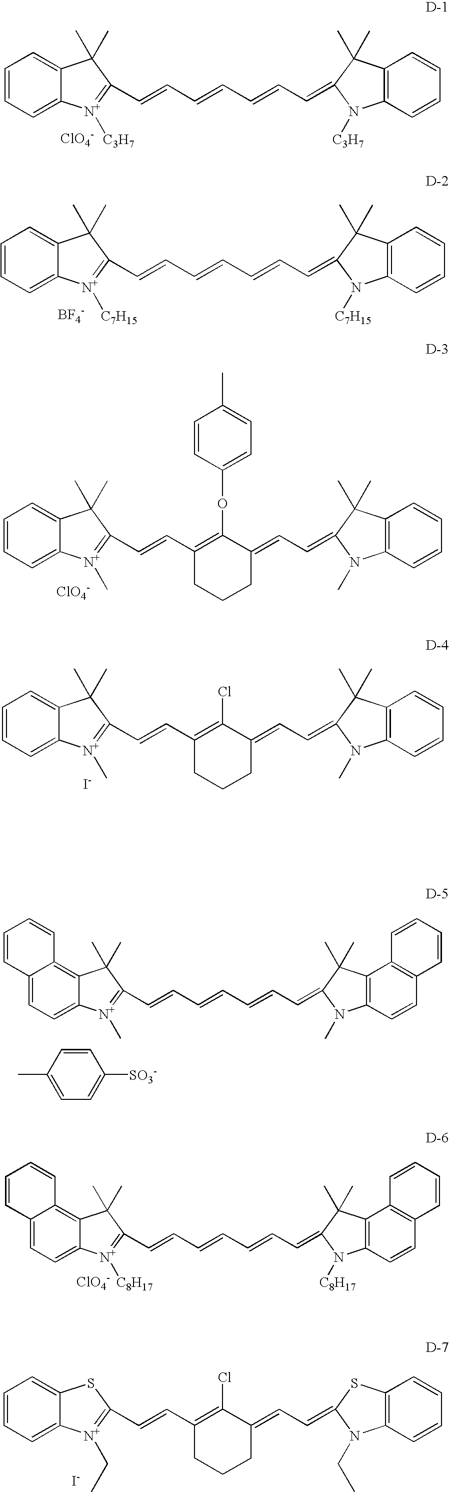

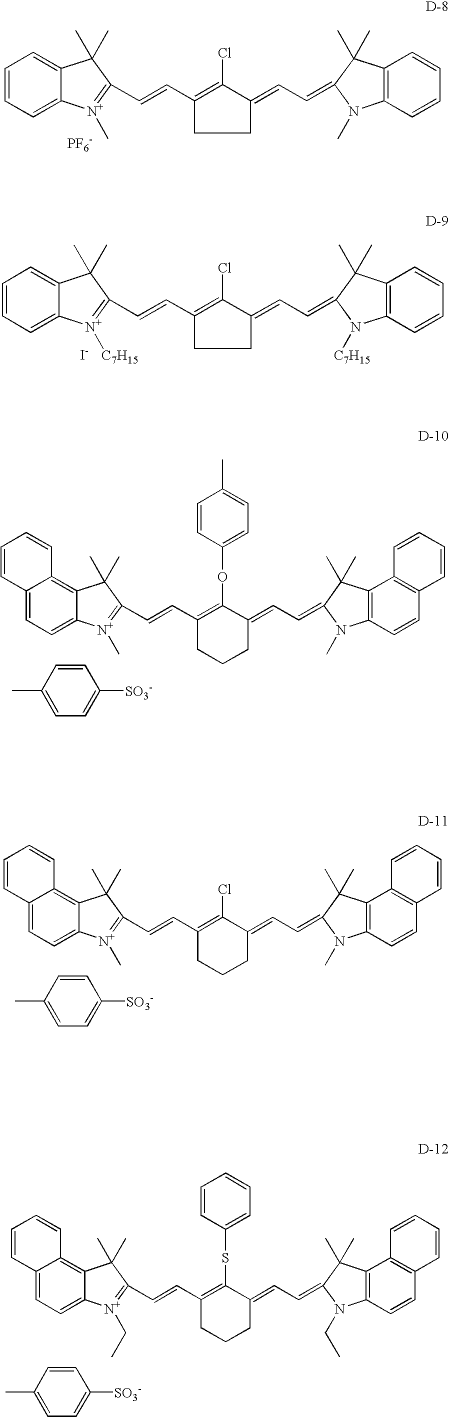

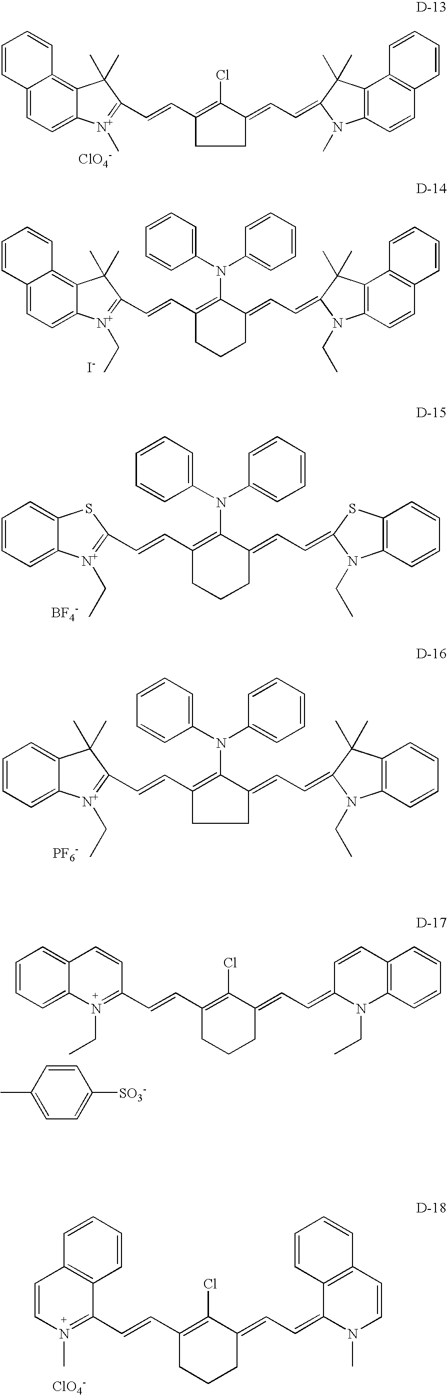

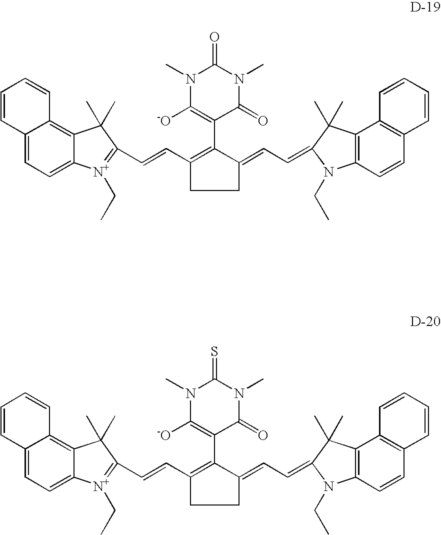

As pigment, commercially available pigments and pigments described in Color Index (C.I.) Binran, “Saishin Ganryo Binran” (ed. by Nihon Ganryo Gijutsu Kyokai, 1977), “Saishin Ganryo Oyo Gijutsu” (CMC Publishing Co., Ltd., 1986), and “Insatsu Inki Gijutsu” (CMC Publishing Co., Ltd., 1984) can be used.

As kinds of the pigment, there are black pigment, yellow pigment, orange pigment, brown pigment, red pigment, violet pigment, blue pigment, green pigment, fluorescent pigment, metal powder pigment and dyes combined with a polymer. These pigments are described in detail in paragraphs [0052] through [0054] of Japanese Patent O.P.I. Publication No. 10-39509, and can be applied in the invention These pigments are preferably ones whose surface is subjected to hydrophilization treatment in view of uniform dispersion in water-soluble image formation layer or water dispersion of image formation layer.

The infrared absorber can be used singly or as an admixture of two or more kinds thereof.

The infrared absorber content of the image formation layer is from 0.01 to 50% by weight, preferably from 0.1 to 20% by weight, and more preferably from 1 to 10% by weight, based on the total solid content of image formation layer.

The image formation layer in the invention preferably contains the following components in addition to those described above

### (Polymeric Binder)

The polymeric binder is one being capable of carring components contained in the image formation layer in the invention. Examples thereof include a polyacrylate resin, a polyvinyl butyral resin, a polyurethane resin, a polyamide resin, a polyester resin, an epoxy resin, a phenol resin, a polycarbonate resin, a polyvinyl butyral resin, a polyvinyl formal resin, shellac, or another natural resin. These can be used as an admixture of two or more thereof.

Preferred is a vinyl copolymer obtained by copolymerization of an acryl monomer, and more preferably a copolymer containing (a) a carboxyl group-containing monomer unit and (b) an alkyl methacrylate or alkyl acrylate unit as the copolymerization component.

Examples of the carboxyl group-containing monomer include an α,β-unsaturated carboxylic acid, for example, acrylic acid, methacrylic acid, maleic acid, maleic anhydride, itaconic acid, itaconic anhydride or a carboxylic acid such as a half ester of phthalic acid with 2-hydroxymethacrylic acid.

Examples of the alkyl methacrylate or alkyl acrylate include an unsubstituted alkyl ester such as methylmethacrylate, ethylmethacrylate, propylmethacrylate, butylmethacrylate, amylmethacrylate, hexylmethacrylate, heptylmethacrylate, octylmethacrylate, nonylmethacrylate, decylmethacrylate, undecylmethacrylate, dodecylmethacrylate, methylacrylate, ethylacrylate, propylacrylate, butylacrylate, amylacrylate, hexylacrylate, heptylacrylate, octylacrylate, nonylacrylate, decylacrylate, undecylacrylate, or dodecylacrylate; a cyclic alkyl ester such as cyclohexyl methacrylate or cyclohexyl acrylate; and a substituted alkyl ester such as benzyl methacrylate, 2-chloroethyl methacrylate, N,N-dimethylaminoethyl methacrylate, glycidyl methacrylate, benzyl acrylate, 2-chloroethyl acrylate, N,N-dimethylaminoethyl acrylate or glycidyl acrylate.

The polymer binder in the invention can further contain, as another monomer unit, a monomer unit derived from the monomer described in the following items (1) through (14):

1) A monomer having an aromatic hydroxy group, for example, o-, (p- or m-) hydroxystyrene, or o-, (p- or m-) hydroxyphenylacrylate;

2) A monomer having an aliphatic hydroxy group, for example, 2-hydroxyethyl acrylate, 2-hydroxyethyl methacrylate, N-methylolacrylamide, N-methylolmethacrylamide, 4-hydroxybutyl acrylate, 4-hydroxybutyl methacrylate, 5-hydroxypentyl acrylate, 5-hydroxypentyl methacrylate, 6-hydroxyhexyl acrylate, 6-hydroxyhexyl methacrylate, N-(2-hydroxyethyl)acrylamide, N-(2-hydroxyethyl)methacrylamide, or hydroxyethyl vinyl ether;

3) A monomer having an aminosulfonyl group, for example, m- or p-aminosulfonylphenyl methacrylate, m- or p-aminosulfonylphenyl acrylate, N-(p-aminosulfonylphenyl)methacrylamide, or N-(p-aminosulfonylphenyl)acrylamide;

4) A monomer having a sulfonamido group, for example, N-(p-toluenesulfonyl)acrylamide, or N-(p-toluenesulfonyl)-methacrylamide;

5) An acrylamide or methacrylamide, for example, acrylamide, methacrylamide, N-ethylacrylamide, N-hexylacrylamide, N-cyclohexylacrylamide, N-phenylacrylamide, N-(4-nitrophenyl)acrylamide, N-ethyl-N-phenylacrylamide, N-(4-hydroxyphenyl)acrylamide or N-(4 hydroxyphenyl)-methacrylamide;

6) A monomer having a fluorinated alkyl group, for example, trifluoroethyl acrylate, trifluoroethyl methacrylate, tetrafluoropropyl methacrylate, hexafluoropropyl methacrylate, octafluoropentyl acrylate, octafluoropentyl methacrylate, heptadecafluorodecyl methacrylate, heptadecafluorodecyl methacrylate, or N-butyl-N-(2-acryloxyethyl)heptadecafluorooctylsulfonamide;

7) A vinyl ether, for example, ethyl vinyl ether, 2-chloroethyl vinyl ether, propyl vinyl ether, butyl vinyl ether, octyl vinyl ether, or phenyl vinyl ether;

8) A vinyl ester, for example, vinyl acetate, vinyl chroloacetate, vinyl butyrate, or vinyl benzoate;

9) A styrene, for example, styrene, methylstyrene, or chloromethystyrene;

10) A vinyl ketone, for example, methyl vinyl ketone, ethyl vinyl ketone, propyl vinyl ketone, or phenyl vinyl ketone;

11) An olefin, for example, ethylene, propylene, isobutylene, butadiene, or isoprene;

12) N-vinylpyrrolidone, N-vinylcarbazole, or N-vinylpyridine,

13) A monomer having a cyano group, for example, acrylonitrile, methacrylonitrile, 2-pentenenitrile, 2-methyl-3-butene nitrile, 2-cyanoethyl acrylate, or o-, m- or p-cyanostyrene;

14) A monomer having an amino group, for example, N,N-diethylaminoethyl methacrylate, N,N-dimethylaminoethyl acrylate, N,N-dimethylaminoethyl methacrylate, polybutadiene urethane acrylate, N,N-dimethylaminopropyl acrylamide, N,N-dimethylacrylamide, acryloylmorpholine, N-isopropylacrylamide, or N,N-diethylacrylamide.

Further another monomer may be copolymerized with the above monomer.

The above vinyl polymers can be synthesized according to solution polymerization, bulk polymerization or suspension polymerization.

The polymer binder in the invention is preferably a vinyl polymer having in the side chain a carboxyl group and a polymerizable double bond. As the polymer binder is also preferred an unsaturated bond-containing copolymer which is obtained by reacting a carboxyl group contained in the above vinyl copolymer molecule with for example, a compound having a (meth)acryloyl group and an epoxy group.

Examples of the compound having a (meth)acryloyl group and an epoxy group in the molecule include glycidyl acrylate, glycidyl methacrylate and an epoxy group-containing unsaturated compound disclosed in Japanese Patent O.P.I. Publication No. 11-271969. Further, an unsaturated bond-containing vinyl copolymer which is obtained by reacting a hydroxyl group contained in the above vinyl copolymer molecule with for example, a compound having a (meth)acryloyl group and an isocyanate group is preferred as the polymer binder. Examples of the compound having an unsaturated bond and an isocyanate group in the molecule include vinyl isocyanate, (meth)acryl isocyanate, 2-(meth)acroyloxyethyl isocyanate, m- or p-isopropenyl-α,α′-dimethylbenzyl isocyanate, and (meth)acryl isocyanate, or 2-(meth)acroyloxyethyl isocyanate is preferred.

The content of the polymeric binder in the image formation layer is preferably from 10 to 90% by weight, more preferably from 15 to 70% by weight, and still more preferably from 20 to 50% by weight, in view of sensitivity.

The image formation layer in the invention may contain a polymerization inhibitor in addition to the components described above, in order to prevent undesired polymerization of the polymerizable compound with an ethylenically unsaturated bond, during the manufacture or storage of the printing plate material. Examples of the polymerization inhibitor include hydroquinone, p-methoxyphenol, di-t-butyl-p-cresol, pyrrogallol, t-butylcatechol, benzoquinone, 4,4′-thiobis(3-methyl-6-t-butylphenol), 2,2′-methylenebis(4-methyl-6-t-butylphenol), N-nitrosophenylhydroxylamine cerous salt, and 2-t-butyl-6-(3-t-butyl-2-hydroxy-5-methylbenzyl)-4-methylphenyl acrylate.

The polymerization inhibitor content is preferably from about 0.01 to about 5% by weight based on the total weight of image formation layer. Further, in order to prevent polymerization induced by oxygen, a higher fatty acid such as behenic acid or a higher fatty acid derivative such as behenic amide may be added to the light sensitive layer, or may be localized on the surface of the light sensitive layer in the course of drying after coating.

The image formation layer in the invention is formed, preparing an image formation layer coating solution, coating the image formation layer coating solution on a support, and drying. Solvents used in the preparation of the image formation layer coating solution include an alcohol such as sec-butanol, isobutanol, n-hexanol or benzyl alcohol; a polyhydric alcohol such as diethylene glycol, triethylene glycol, tetraethylene glycol, or 1,5-pentanediol; an ether such as propylene glycol monobutyl ether, dipropylene glycol monomethyl ether, or tripropylene glycol monomethyl ether; a ketone or aldehyde such as diacetone alcohol, cyclohexanone, or methyl cyclohexanone; and an ester such as ethyl lactate, butyl lactates diethyl oxalate or methyl benzoate.

The image formation layer coating solution contains preferably a surfactant. A fluorine-containing surfactant is especially preferred as the surfactant.

### (Undercoat Layer)

An undercoat layer may be provided between the support and the image formation layer in the invention. The undercoat layer is preferably a layer containing a water-soluble compound. The following compounds are cited as the water-soluble compound.

Examples of the water-soluble compound include glycols such as ethylene glycol, diethylene glycol, triethylene glycol, propylene glycol, dipropylene glycol and tripropylene glycol, and their ether or ester derivatives; polyhydroxy compounds such as glycerin and pentaerythritol; organic amines such as triethanolamine, diethanolamine and monoethanolamine, and their salt; quaternary ammonium salts such as tetraethylammonium bromide; organic sulfonic acids such as toluene sulfonic acid and benzene sulfonic acid, and their salts; organic phosphonic acids such as phenylphosphonic acid and their salts; organic carboxylic acids such as tartaric acid, oxalic acid, citric acid, malic acid, lactic acid, gluconic acid and amino acid and their salts; phosphoric acid salts (trisodium phosphate, disodium hydrogenphosphate, sodium dihydrogenphosphate); carbonates (sodium carbonate, guanidine carbonate); other water-soluble organic or inorganic salts; saccharides (monosaccharides, oligosaccharides, etc.); polysaccharides; phosphoric acid esters having a polypropylene oxide chain or a polyethylene oxide chain; polypropylene oxide; polyvinyl alcohol; polyethylene glycol (PEG); polyvinyl ether; conjugated diene polymer latexes such as styrene-butadiene copolymer and methyl methacrylate-butadiene copolymer; acryl polymer latex; vinyl polymer latex; and water-soluble polymers such as polyacrylamide and polyvinyl pyrrolidone. Among these, phosphoric acid esters having a polyethylene oxide chain are preferably used.

### (Support)

The support having a hydrophilic surface in the invention is a substrate having a surface such that when a thermosensitive layer is removed, water receptive non-image portions are formed on the surface. As the support can be used a substrate whose surface is subjected to hydrophilization processing to have a hydrophilic surface or a substrate coated with a hydrophilic layer containing a hydrophilic substance.

As the support in the invention, known materials used as a support for a printing plate can be used. Examples thereof include paper sheet treated with a metal plate, a plastic film or polyolefin and a composite substrate in which the above materials are suitably laminated.

The thickness of the support is not specifically limited, as long as it can be mounted on a printing press, but the support with a thickness of from 50 to 500 μm is generally easy to handle.

As the support in the invention, a metal plate whose surface is subjected to hydrophilization treatment is preferably used.

As the metal plate, a plate of iron, stainless steel or aluminum is used. An aluminum or aluminum alloy plate (hereinafter, each referred to as aluminum plate) is preferred in view of gravity or rigidity, and one (so-called grained aluminum plate) which is subjected to known surface roughening treatment, anodizing treatment or surface hydrophilization treatment is more preferred.

As the aluminum alloy used as a substrate, there can be used various ones including an alloy of aluminum and a metal such as silicon, copper, manganese, magnesium, chromium, zinc, lead, bismuth, nickel, titanium, sodium or iron.

It is preferable that an aluminum plate used as a substrate is subjected to degreasing treatment for removing rolling oil prior to surface roughening (graining). The degreasing treatments include degreasing treatment employing solvents such as trichlene and thinner, and an emulsion degreasing treatment employing an emulsion such as kerosene or triethanol. It is also possible to use an aqueous alkali solution such as caustic soda for the degreasing treatment. When an aqueous alkali solution such as caustic soda is used for the degreasing treatment, it is possible to remove soils and an oxidized film which can not be removed by the above-mentioned degreasing treatment alone. When an aqueous alkali solution such as caustic soda is used for the degreasing treatment, the resulting support is preferably subjected to desmut treatment in an aqueous solution of an acid such as phosphoric acid, nitric acid, sulfuric acid, chromic acid, or a mixture thereof, since smut is produced on the surface of the support. As the surface roughening methods, there are a mechanical method and an electrolytically etching method.

Though there is no restriction for the mechanical surface roughening method, a brushing roughening method and a honing roughening method are preferable. The brushing roughening method is carried out by rubbing the surface of the substrate with a rotating brush with a brush hair with a diameter of 0.2 to 0.8 mm, while supplying slurry in which volcanic ash particles with a particle size of 10 to 100 μm are dispersed in water to the surface of the substrate. The honing roughening method is carried out by ejecting obliquely slurry with pressure applied from nozzles to the surface of the substrate, the slurry containing volcanic ash particles with a particle size of 10 to 100 μm dispersed in water. The surface roughening can be also carried out by laminating the substrate surface with a sheet whose surface was coated with abrasive particles with a particle size of from 10 to 100 μm at intervals of 100 to 200 μm and at a density of 2.5×10³ to 10×10³/cm², and applying pressure to the sheet to transfer the roughened pattern of the sheet to the substrate, whereby the substrate is surface-roughened.

After the substrate has been roughened mechanically, it is preferably dipped in an acid or an aqueous alkali solution in order to remove abrasives and aluminum dust, etc. which have been embedded in the surface of the substrate. Examples of the acid include sulfuric acid, persulfuric acid, hydrofluoric acid, phosphoric acid, nitric acid and hydrochloric acid, and examples of the alkali include sodium hydroxide and potassium hydroxide. Among those mentioned above, an aqueous alkali solution of for example, sodium hydroxide is preferably used. The dissolution amount of aluminum in the substrate surface is preferably 0.5 to 5 g/m². After the substrate has been dipped in the aqueous alkali solution, it is preferable for the support to be dipped in an acid such as phosphoric acid, nitric acid, sulfuric acid and chromic acid, or in a mixed acid thereof, for neutralization.

Though there is no restriction for the electrolytic surface roughening method, a method, in which the substrate is electrolytically surface roughened in an acidic electrolytic solution employing alternating current, is preferred. Though an acidic electrolytic solution generally used for the electrolytic surface roughening can be used, it is preferable to use an electrolytic solution of hydrochloric acid or that of nitric acid. The electrolytic surface roughening method disclosed in Japanese Patent Publication No. 48-28123, British Patent No. 896,563 and Japanese Patent O.P.I. Publication No. 53-67507 can be used. In the electrolytic surface roughening method, voltage applied is generally from 1 to 50 V, and preferably from 10 to 30 V. The current density used can be selected from the range from 10 to 200 A/dm², and is preferably from 50 to 150 A/dm². The quantity of electricity can be selected from the range of from 100 to 5000 C/dm², and is preferably 100 to 2000 C/dm². The temperature during the electrolytically surface roughening may be in the range of from 10 to 50° C., and is preferably from 15 to 45° C.

When the substrate is electrolytically surface roughened by using an electrolytic solution of nitric acid, voltage applied is generally from 1 to 50 V, and preferably from 10 to 30 V. The current density used can be selected from the range from 10 to 200 A/dm², and is preferably from 20 to 100 A/dm². The quantity of electricity can be selected from the range of from 100 to 5000 C/dm², and is preferably 100 to 2000 C/dm². The temperature during the electrolytically surface roughening may be in the range of from 10 to 50° C., and is preferably from 15 to 45° C. The nitric acid concentration in the electrolytic solution is preferably from 0.1% by weight to 5% by weight. It is possible to optionally add, to the electrolytic solution, nitrates, chlorides, amines, aldehydes, phosphoric acid, chromic acid, boric acid, acetic acid or oxalic acid.

When the substrate is electrolytically surface roughened by using an electrolytic solution of hydrochloric acid, voltage applied is generally from 1 to 50 V, and preferably from 2 to 30 V. The current density used can be selected from the range from 10 to 200 A/dm², and is preferably from 50 to 150 A/dm². The quantity of electricity can be selected from the range of from 100 to 5000 C/dm², preferably 100 to 2000 C/dm², and more preferably from 200 to 1000 C/dm². The temperature during the electrolytically surface roughening may be in the range of from 10 to 50° C., and is preferably from 15 to 45° C. The hydrochloric acid concentration in the electrolytic solution is preferably from 0.1% by weight to 5% by weight.

After the substrate has been electrolytically surface roughened, it is preferably dipped in an acid or an aqueous alkali solution in order to remove aluminum dust, etc produced in the surface of the substrate. Examples of the acid include sulfuric acid, persulfuric acid, hydrofluoric acid, phosphoric acid, nitric acid and hydrochloric acid, and examples of the alkali include sodium hydroxide and potassium hydroxide.

Among those mentioned above, the aqueous alkali solution is preferably used. The dissolution amount of aluminum in the substrate surface is preferably 0.5 to 5 g/m². After the substrate has been dipped in the aqueous alkali solution, it is preferable for the substrate to be dipped in an acid such as phosphoric acid, nitric acid, sulfuric acid and chromic acid, or in a mixed acid thereof, for neutralization.

The mechanical surface roughening and electrolytic surface roughening may be carried out singly, and the mechanical surface roughening followed by the electrolytic surface roughening may be carried out.

After the surface roughening, anodizing treatment may be carried out. There is no restriction in particular for the method of anodizing treatment used in the invention, and known methods can be used. The anodizing treatment forms an anodization film on the surface of the substrate. For the anodizing treatment there is preferably used a method of applying a current density of from 1 to 10 A/dm² to an aqueous solution containing sulfuric acid and/or phosphoric acid in a concentration of from 10 to 50%, as an electrolytic solution. However, it is also possible to use a method of applying a high current density to sulfuric acid as described in U.S. Pat. No. 1,412,768, a method to electrolytically etching the support in phosphoric acid as described in U.S. Pat. No. 3,511,661, or a method of employing a solution containing two or more kinds of chromic acid, oxalic acid, malonic acid, etc. The coated amount of the formed anodization film is suitably 1 to 50 mg/dm², and preferably 10 to 40 mg/dm². The coated amount of the formed anodization film can be obtained from the weight difference between the aluminum plates before and after dissolution of the anodization film. The anodization film of the aluminum plate is dissolved employing for example, an aqueous phosphoric acid chromic acid solution which is prepared by dissolving 35 ml of 85% by weight phosphoric acid and 20 g of chromium (IV) oxide in 1 liter of water.

The substrate, which has been subjected to anodizing treatment, is optionally subjected to sealing treatment. For the sealing treatment, it is possible to use known methods using hot water, boiling water, steam, a sodium silicate solution, an aqueous dichromate solution, a nitrite solution and an ammonium acetate solution.

As the hydrophilization processing method after the above treatments, a method is preferred which undercoats, on the substrate, a water soluble resin such as polyvinyl phosphonic acid, a polymer or copolymer having a sulfonic acid group in the side chain, polyacrylic acid, a water soluble metal salt such as zinc borate, a yellow dye, an amine salt, and so on. The sol-gel treatment substrate disclosed in Japanese Patent O.P.I. Publication No. 5-304358, which has a functional group capable of causing addition reaction by radicals as a covalent bond, is suitably used.

Examples of the plastic film used as a substrate include films of polyethylene terephthalate, polyethylene naphthalate, polyimide, polyamide, polycarbonate, polysulfone, polyphenylene oxide, cellulose esters and the like.

### (Exposure)

In the invention, the printing plate material is preferably exposed with laser to form an image.

It is preferred that exposure employing a thermal laser as the laser is carried out to form an image.

For example, scanning exposure is preferred which is carried out employing laser which emits light having an infrared or near-infrared wavelength range, i.e., a 700 to 1500 nm wavelength range.

As the laser, a gas laser can be used, but a semiconductor laser, which emits near-infrared light, is preferably used.

The scanning exposure device may be any as long as it can form an image on the surface of a printing plate material employing the semiconductor laser, based on image formation from a computer.

Generally, the scanning exposure devices include those employing the following processes.

(1) a process in which a printing plate material provided on a fixed horizontal plate is scanning exposed in two dimensions, employing one or several laser beams.

(2) a process in which the surface of a printing plate material provided along the inner peripheral wall of a fixed cylinder is subjected to scanning exposure in the rotational direction (in the main scanning direction) of the cylinder, employing one or several lasers located inside the cylinder, moving the lasers in the normal direction (in the sub-scanning direction) to the rotational direction of the cylinder.

(3) a process in which the surface of a printing plate material provided along the outer peripheral wall of a fixed cylinder is subjected to scanning exposure in the rotational direction (in the main scanning direction) of the cylinder, employing one or several lasers located outside the cylinder, moving the lasers in the normal direction (in the sub-scanning direction) to the rotational direction of the cylinder. The process (3) is used particularly when a printing plate material mounted on a plate cylinder of a printing press is scanning exposed.

### (Printing)

A conventional planographic printing method employing dampening water and printing ink can be applied to an imagewise exposed printing plate material.

In printing, dampening water, which does not substantially contains isopropanol, is preferably used. The dampening water which does not substantially contains isopropanol means a dampening water containing isopropanol in an amount of not more than 0.5% by weight based on the content of water.

It is preferred that a printing plate material, after imagewise exposed employing laser, is mounted on a plate cylinder of a printing press, developed with dampening water or both dampening water and printing ink to form an image, and then printing is carried out.

The printing plate material is mounted on a plate cylinder of a printing press and imagewise exposed, or the printing plate material after imagewise exposed is mounted on a plate cylinder of a printing press. Subsequently, the printing plate material is brought into contact with a dampening roller and an inking roller while rotating the plate cylinder, whereby a thermosensitive image formation layer at non-image portions can be removed on the printing press.

The removal of the image formation layer at non-image portions as described above, that is, on-press development will be explained below.

Removal on a press of the thermosensitive image formation layer at non-image portions (unexposed portions) of a printing plate material can be carried out by bringing a dampening roller and an inking roller into contact with the image formation layer while rotating the plate cylinder, or by various sequences such as those described below or another appropriate sequence.

The supplied amount of dampening water may be adjusted to be greater or smaller than the amount necessary to be supplied in printing, and the adjustment may be carried out stepwise or continuously.

(1) A dampening roller is brought into contact with the image formation layer of a printing plate material on the plate cylinder during one to several tens of rotations of the plate cylinder, and then an inking roller brought into contact with the image formation layer during the next one to tens of rotations of the plate cylinder. Thereafter, printing is carried out.

(2) An inking roller is brought into contact with the image formation layer of a printing plate material on the plate cylinder during one to several tens of rotations of the plate cylinder, and then a dampening roller brought into contact with the image formation layer during the next one to tens of rotations of the plate cylinder. Thereafter, printing is carried out.

(3) An inking roller and a dampening roller are brought into contact with the image formation layer of a printing plate material on the plate cylinder during one to several tens of rotations of the plate cylinder. Thereafter, printing is carried out.

The thermosensitive image formation layer in the invention is a layer prepared by coating on a support an aqueous dispersion of a specific blocked isocyanate compound and drying. Accordingly, even the printing plate material after storage at a relatively high temperature can be subjected to on-press development, and can form a good image.

### EXAMPLES

The present invention will be explained below employing the following examples. In the examples, “parts” is parts by weight, unless otherwise specifically specified.

### (Preparation of Support)

A support was prepared as follows.

### Support

A 0.24 mm thick aluminum plate (material 1050, refining H16) was immersed in an aqueous 1% by weight sodium hydroxide solution at 50° C. to give an aluminum dissolution amount of 2 g/m², washed with water, immersed in an aqueous 5% by weight nitric acid solution at 25° C. for 30 seconds to neutralize, and then washed with water.

Subsequently, the aluminum plate was subjected to an electrolytic surface-roughening treatment in an electrolytic solution containing 11 g/L of hydrochloric acid, 10 g/L of acetic acid and 8 g/L of aluminum at a peak current density of 80 A/dm² employing an alternating current with a sine waveform, in which the distance between the plate surface and the electrode was 10 mm. The electrolytic surface-roughening treatment was divided into 8 treatments, in which the quantity of electricity used in one treatment (at a positive polarity) was 60 C/dm², and the total quantity of electricity used (at a positive polarity) was 480 C/dm². Standby time of 3 seconds, during which no surface-roughening treatment was carried out, was provided after each of the separate electrolytic surface-roughening treatments.

Subsequently, the resulting aluminum plate was immersed in an aqueous 10% by weight phosphoric acid solution at 50° C. and etched so that the aluminum etching amount (including smut produced on the surface) was 0.65 g/m², and washed with water.

Subsequently, the aluminum plate was subjected to anodizing treatment in an aqueous 20% by weight sulfuric acid solution at a current density of 5 A/dm² to form an anodized film with a coating amount of 2.5 g/m², and washed with water.

The washed surface of the plate was squeegeed, and the resulting plate was immersed in an aqueous 1% by weight sodium silicate No. 3 solution at 30° C. for 15 seconds, washed with water, and dried at 80° C. for 5 minutes. Thus, the support 1 was obtained.

The surface configuration parameter Ra of the support obtained above was determined according to the following method. The Ra of the support 1 was 0.44 μm.

A platinum-rhodium layer with a thickness of 1.5 nm was vacuum-deposited onto a sample surface, and the surface roughness was measured under condition of a magnification of 40, employing a non-contact three dimensional surface roughness measuring device RST plus produced by WYKO Co., Ltd., (in which the measurement area is 111.2 μm×149.7 μm, the measuring points were 236×368, and a degree of resolution was about 0.5 μm).

The resulting measurements were subjected to slope correction and to filtering treatment of Median Smoothing, and Ra was determined after noises were removed. Five portions of each sample were measured and the average of the measurements was calculated.

### (Preparation of Ultraviolet Absorbing Latex)

### Ultraviolet Absorbing Latex 1:

Fifty-five parts by weight of PVA (with a degree of polymerization of 550 and a degree of saponification of 99.0 mol %), 5 parts by weight of an anionic surfactant Aerosol OT-75 (produced by Mitsui Cytec Ltd.) and 300 ml of ion-exchange water were placed in a glass vessel with a reflux condenser, a funnel, a thermometer, a nitrogen introducing tube and a stirrer, heated to be a solution, and adjusted to a pH of 4.0 with a diluted sulfuric acid solution.

Subsequently, the resulting solution was added with 80 parts by weight of styrene and 20 parts by weight of ultraviolet absorbing monomer 2-(2′-hydroxy-5′-methacryloxyethylphenyl)-2-benzotriazole, and heated to 70° C. under nitrogen atmosphere.

Successively, 10 g of an aqueous 2% potassium persulfate solution were added to the resulting solution to initiate polymerization. After 5 hours' polymerization, ultraviolet absorbing latex 1 was prepared which had a solid concentration of 33.2% and an average particle size of 85 nm.

### Ultraviolet Absorbing Latex 2:

Ultraviolet absorbing latex 2 was prepared in the same manner as ultraviolet absorbing latex 1, except that 80 parts by weight of styrene were replaced with 50 parts by weight of styrene and 30 parts by weight of MMA. The average particle size of Ultraviolet absorbing latex 2 was 80 nm.

### Preparation of Image Formation Layer

The components in the following composition were sufficiently mixed with stirring, and filtered to obtain an image formation layer coating solution with a solid content of 10% by weight.

Image Formation Layer Coating Solution Composition

| | |
|---|---|
| Four percent by weight MEK solution of | 5.0 parts |
| infrared absorber represented by formula described later | |
| Fifty percent by weight MEK solution of | 9.0 parts |
| pentaerythritol tetracrylate | |
| Twenty percent by weight MEK solution of | 22.5 parts |
| polyvinyl butyral Eslec BM-S (produced by Sekisui Kagaku | |
| Kogyo Co., Ltd.) | |
| Five percent by weight MEK solution of | 12.0 parts |
| polymerization initiator represented by formula described | |
| later | |
| Two percent by weight IPA (isopropanol) | 10.0 parts |
| solution of a phosphoric acid ester compound represented by | |
| formula described later | |
| MEK (Methyl ethyl ketone) | 41.5 parts |

Infrared Absorber

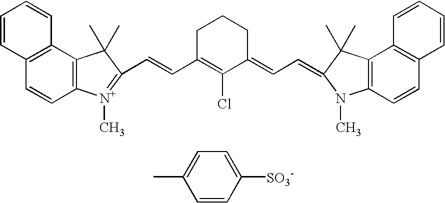

Polymerization Initiator

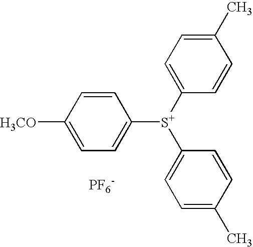

phosphoric Acid Ester Compound

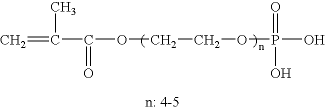

### (Preparation of Overcoat Layer)

The components in the following composition were sufficiently mixed with stirring, and filtered to obtain overcoat layer coating solutions OC1 through OC5 with a solid content of 8% by weight.

Overcoat Layer Coating Solution Composition (Values in Table Show Parts by Weight.)

TABLE 1

| Components | OC1 | OC2 | OC3 | OC4 | OC5 | OC6 | OC7 |
|---|---|---|---|---|---|---|---|
| a) | 79.92 | 55.92 | 39.92 | 55.92 | 47.92 | 59.92 | 51.92 |
| Ultraviolet | | | | 7.23 | 9.64 | | |
| absorbing | | | | | | | |
| latex 1 | | | | | | | |
| Ultraviolet | | | | | | 6.02 | 8.43 |
| absorbing | | | | | | | |
| latex 2 | | | | | | | |
| b) | | 12.00 | 20.00 | | | | |
| c) | 0.80 | 0.80 | 0.80 | 0.80 | 0.80 | 0.80 | 0.80 |
| Pure water | 19.28 | 31.28 | 39.28 | 36.05 | 41.64 | 33.26 | 38.85 |

a) Aqueous 10% by weight solution of PVA-105 (produced by Kuraray Co., Ltd.)
b) Pigment dispersion: Permanent Yellow GR, average particle size: 200 nm, solid content of 20% by weight
c) Surfactant: Aqueous solution of Surfinol 465 (produced by Air Products Co., Ltd.), solid content of 1% by weight

### (Preparation of Printing Plate Material)

### [Printing Plate Material 1]

A 0.2% by weight IPA solution of the phosphoric acid ester compound represented by formula above was coated on the support 1 obtained above, employing a wire bar, and dried at 100° C. for one minute to give a dry coating amount of 10 mg/m².

Subsequently, the light sensitive layer coating solution above was coated on the resulting support, employing a wire bar, and dried at 60° C. for three minutes to give a dry coating amount of 1.2 g/m².

Successively, the overcoat layer coating solution OC1 was coated, employing a wire bar, and dried at 60° C. for three minutes to give a dry coating amount of 1.2 μm².

The resulting material was subjected to aging treatment to obtain a printing plate material 1.

### [Printing Plate Materials 2 Through 7]

Printing plate materials 2 through 7 were prepared in the same manner as printing plate material 1, except that OC2 through OC7 were used instead of OC1, respectively.

Operations after coating of the light sensitive layer were carried out under yellow light, and the printing plate materials, when not handled, were placed in a light-shielded room.

### (Evaluation Method)

The printing plate materials obtained above, unexposed samples were placed under a white fluorescent lamp (FLR40SW produced by Mitsubishi Denki Co., Ltd.) at 25° C. and 50% RH so that the light sensitive layer thereof was exposed to the white fluorescent lamp at an illuminance of 400 lux for 5 minutes, 15 minutes, 30 minutes, 1 hour, 3 hours, 6 hours and 9 hours.

The resulting samples and samples which were not placed under the white fluorescent lamp were exposed according to the following method.

### [Exposure Employing Infrared Laser]

Each of the samples was mounted on an exposure drum, and fixed. Exposure was carried out employing laser, beams having a wavelength of 830 nm and a beam spot size of 18 μm at a resolution of 2400 dpi (“dpi” herein shows the number of dots per 2.54 cm) and at a screen line number of 175 to form an image. The image pattern used for exposure had a solid image, a dot image with a dot area of 1 to 99%. Exposure energy used was 150, 200, 250, 300 and 350 mJ/cm², and the image pattern was included at each exposure energy level.

### [Printing Method]

Printing was carried out employing a printing press, DAIYA 1F-1 produced by Mitsubishi Jukogyo Co., Ltd., wherein coated paper, dampening water, a 2% by weight solution of Astromark 3 (produced by Nikken Kagaku Kenkyusyo Co., Ltd.), and printing ink (Toyo King Hyunity MZ Magenta, produced by Toyo Ink Manufacturing Co.) were employed.

Each of the exposed samples was mounted on a plate cylinder of the printing press, and printing was carried out in the same printing condition and printing sequence as a conventional PS plate to obtain 100 prints.

### [Initial Printability]

Regarding each printing plate material sample, which was not placed under the white fluorescent lamp, the number of prints printed until a print with good image was obtained was determined. Herein, the good image was defined as an image in which a 90% dot area was reproduced, a solid image had a density of not less than 1.5, and stains were not found at the background. When good image was not obtained in the 100th print, initial printability was rated as 100 or more.

The results are shown in Table 2. The evaluated image was one formed at exposure energy corresponding to sensitivity described later of each printing plate material sample.

### [Evaluation of Sensitivity]

When one hundredth print was observed through a loupe in the 100 prints printed employing each printing plate material sample which was not placed under the white fluorescent lamp, the minimum exposure energy at which an image with a 3% dot area was fully reproduced without dot loss was determined and evaluated as a measure of sensitivity. The results are shown in Table 2.

### [Evaluation of Stability Under Room Light]

When one hundredth print was observed through a loupe in the 100 prints printed employing each printing plate material sample which was placed under the white fluorescent lamp, the longest time, during which the printing plate material sample was placed under the white fluorescent lamp, providing an image with a 90% dot area fully reproduced was determined and evaluated as a measure of stability under room light. When an image with a 90% dot area is fully reproduced in the sample placed under the white fluorescent lamp for 9 hours, stability under room light was rated as 9 hours or more. The results are shown in Table 2. The evaluated image was one formed at exposure energy corresponding to sensitivity described later of each printing plate material sample.

### [Contamination of Printing Press]

Each roller of the printing press was washed, the ink roller was supplied with a fresh ink, and the dampening water was replaced with a fresh dampening water. Firstly, printing was carried out employing a PS plate (having solid image portions) to obtain 100 prints. Subsequently, employing each printing plate material sample (which was not placed under the white fluorescent lamp), on-press development was carried out in the same manner as above and printing was carried out to obtain 100 prints.

Subsequently, the sample was replaced with a new one, and the same procedure as above was carried out to obtain 100 prints. This procedure was repeated 10 times.

After 10 samples were subjected to on-press development as above with respect to each printing plate material sample, contamination of the printing press was checked and evaluated. The evaluation method and evaluation measure will be described below. The results are shown in Table 2.

### [Ink Contamination]

The L*a*b* value of the solid portions in the 100^{th} print printed employing the PS plate and the solid portions in the 100^{th} print printed employing the 10^{th} printing plate material sample was measured through X-Rite-520 (produced by X-Rite Co., Ltd.), and color difference E was determined. Ink contamination was evaluated according to the following criteria.

A: ΔE is less than 2.
B: ΔE is from 2 to less than 5.
C: ΔE is not less than 5.

### [Dampening Roller Contamination]

After 10 samples were subjected to on-press development as above with respect to each printing plate material sample, contamination of the dampening roller surface was visually observed and evaluated according to the following criteria.

A: No Substantial coloration was observed
B: Slight stain of color different from that of printing ink was observed.
C: Apparent stain of color different from that of printing ink was observed.

As is apparent from Table 2, the inventive printing plate material samples improve stability under room light while maintaining sensitivity and initial printability, and reduce contamination of a printing press.

TABLE 2

| Sample | | | | | (h) | | |
|---|---|---|---|---|---|---|---|
| No. | (d) | (e) | (f) | (g) | (i) | (j) | Remarks |
| 1 | OC1 | 50 | 200 | 1 hour | A | A | Comp. |
| 2 | OC2 | 35 | 250 | 3 hours | B | B | Comp. |
| 3 | OC3 | 35 | 350 | 6 hours | C | C | Comp. |
| 4 | OC4 | 25 | 200 | 9 hours or more | A | A | Inv. |
| 5 | OC5 | 25 | 250 | 9 hours or more | A | A | Inv. |
| 6 | OC6 | 25 | 200 | 9 hours or more | A | A | Inv. |
| 7 | OC7 | 25 | 200 | 9 hours or more | A | A | Inv. |

Comp.: Comparative, Inv.: Inventive
(d): Overcoat Layer Coating Solution No.
(e): Initial Printability (Number)
(f): Sensitivity (mJ/cm²)
(g): Stability under Room Light
(h): Contamination of Printing Press
(i): Ink Contamination
(j): Dampening roller contamination

1. A printing plate material comprising a support having a hydrophilic surface, and provided thereon, an on-press developable image formation layer (A) and an on-press developable overcoat layer (B) in that order, wherein the on-press developable image formation layer (A) contains (a1) through (a3) as shown below, and the on-press developable overcoat layer (B) contains (b) as shown below:
(a1) an radically polymerizable compound with an ethylenically unsaturated bond
(a2) an polymerization initiator capable of generating a radical on reaction with an infrared absorber
(a3) an infrared absorber
(b) water-insoluble particles formed of a composite of a water-insoluble compound (b1) having no ultraviolet absorbing capability and a compound (b2) having an ultraviolet absorbing capability.

2. The printing plate material of claim 1, wherein the water-insoluble particles (b) are thermoplastic resin particles having an ultraviolet absorbing capability.

3. The printing plate material of claim 1, wherein the compound (b2) having an ultraviolet absorbing capability has a benzotriazole partial structure or a benzophenone partial structure.

4. The printing plate material of claim 3, wherein the benzotriazole partial structure is represented by the following formula (1): 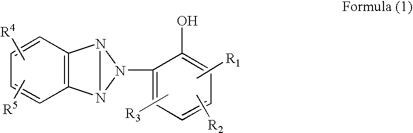
wherein R₁, R₂, R₃, R₄ and R₅ may be the same or different, and independently represent a hydrogen atom, a halogen atom, a nitro group, a hydroxyl group, an alkyl group, an alkenyl group, an aryl group, an alkoxy group, an acyloxy group, an aryloxy group, an alkylthio group, an arylthio group, a mono- or di-alkylamino group, an acylamino group or a 5- or 6-membered heterocyclic ring containing an oxygen or nitrogen atom, provided that R₄ and R₅ may combine with each other to form a hydrocarbon ring.

5. The printing plate material of claim 3, wherein the benzotriazole partial structure is represented by the following formula (2): 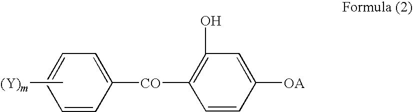
wherein Y represents a hydrogen atom, a halogen atom, an alkyl group, an alkenyl group or a phenyl group; A represents a hydrogen atom, an alkyl group, an alkenyl group, a phenyl group, a cycloalkyl group, an alkylcarbonyl group, an alkylsulfonyl group or —CO(NH)ₙ₋₁-D, in which D represents an alkyl group, an alkenyl group or a substituted or unsubstituted phenyl group and n represents 1 or 2; and m represents 1 or 2.

6. The printing plate material of claim 1, wherein the average particle size of the water-insoluble particles (b) is from 10 to 150 nm.

7. The printing plate material of claim 1, wherein the content of the water-insoluble particles (b) in the overcoat layer is from 15 to 60% by weight.

8. The printing plate material of claim 1, wherein the overcoat layer further contains a polymeric binder.

9. The printing plate material of claim 8, wherein the polymeric binder is polyvinyl alcohol or polyvinyl pyrrolidone.

10. The printing plate material of claim 1, wherein the thickness of the overcoat layer is from 0.1 to 5.0 μm.

11. The printing plate material of claim 1, wherein the content of the radically polymerizable compound with an ethylenically unsaturated bond in the image formation layer from 15 to 60% by weight.

12. The printing plate material of claim 1, wherein the content of the polymerization initiator is from about 0.1 to about 20% by weight.

13. The printing plate material of claim 1, wherein the content of the infrared absorber in the image formation layer is from 1 to 10% by weight.

14. The printing plate material of claim 1, wherein the support having a hydrophilic surface is an aluminum plate subjected to hydrophilization treatment.
